(19) United States
(12) Patent Application Publication
(10) Pub. No.: US 2024/0008282 A1
(43) Pub. Date: Jan. 4, 2024

(54) SEMICONDUCTOR DEVICE INCLUDING OXIDE CHANNEL LAYER AND FERROELECTRIC LAYER AND METHOD OF FABRICATING THE SAME

(71) Applicant: SK hynix Inc., Icheon-si (KR)

(72) Inventor: Mir IM, Icheon-si (KR)

(21) Appl. No.: 18/059,547

(22) Filed: Nov. 29, 2022

(30) Foreign Application Priority Data
Jul. 1, 2022 (KR) 10-2022-0081528

(51) Int. Cl. H01L 27/11597; H01L 27/1159; H01L 27/11592

(52) U.S. Cl. CPC H01L 27/11597; H01L 27/1159; H01L 27/11592

(57) ABSTRACT

A semiconductor device according to an embodiment includes a substrate, a source electrode layer and a drain electrode layer that are disposed over the substrate to be spaced apart from each other in a direction substantially perpendicular to a surface of the substrate, first and second oxide channel layers the extend in the direction substantially perpendicular to the surface of the substrate between the source electrode layer and the drain electrode layer, a ferroelectric layer disposed adjacent to the first and second oxide channel layers, and a gate electrode layer disposed on the ferroelectric layer. The first and second oxide channel layers have different band gap energies from each other.

### CROSS-REFERENCE TO RELATED APPLICATIONS

The present application claims priority under 35 U.S.C. § 119(a) to Korean Application No. 10-2022-0081528, filed on Jul. 1, 2022, which is incorporated herein by reference in its entirety.

### BACKGROUND

### 1. Technical Field

The present disclosure generally relates to a semiconductor device and, more particularly, to a semiconductor device including an oxide channel layer and a ferroelectric layer, and a method of fabricating the same.

### 2. Related Art

Research on semiconductor devices capable of ensuring structural stability and operational reliability in a reduced space continues to address trends in decreasing design rules and increasing degree of integration. As an example, in the case of a memory device, a technique for increasing the density of memory cells by reducing the area of the memory cell and improving the endurance of signal information stored in the memory cells is being studied.

As a candidate for a memory device capable of achieving the above purposes, a ferroelectric field effect transistor has been proposed. The ferroelectric field effect transistor may be a memory device that stores signal information using remanent polarization states with different orientations in a ferroelectric layer that is also a gate dielectric layer.

### SUMMARY

A semiconductor device according to an embodiment of the present disclosure may include a substrate, a source electrode layer and a drain electrode layer that are disposed over the substrate to be spaced apart from each other in a direction substantially perpendicular to a surface of the substrate, first and second oxide channel layers that extend in the direction substantially perpendicular to the surface of the substrate between the source electrode layer and the drain electrode, a ferroelectric layer disposed adjacent to the first and second oxide channel layers, and a gate electrode layer disposed on the ferroelectric layer. The first and second oxide channel layers may have different band gap energies from each other.

In a method of fabricating a semiconductor device, a stack structure including a source electrode material layer, a first passivation material layer, a gate electrode material layer, a second passivation material layer, and a drain electrode material layer, which are sequentially stacked over a substrate may be formed. A hole pattern penetrating the stack structure over the substrate may be formed. The first and second passivation material layers may be selectively recessed in the hole pattern to form a first recess space in an inner direction substantially parallel to a surface of the substrate. The gate electrode material layer may be selectively recessed in the hole pattern to form a second recess space. The second recess space extends beyond the first recess space in the inner direction. A ferroelectric layer may be formed in the second recess space. A first channel material layer and a second channel material layer may be sequentially formed in the first recess space. The second channel material layer has a different band gap energy from the first channel material layer. A third passivation material layer covering at least the second channel material layer may be formed in the hole pattern.

### BRIEF DESCRIPTION OF THE DRAWINGS

FIG. 1 is a perspective view schematically illustrating a semiconductor device according to an embodiment of the present disclosure.

FIG. 2 is a cross-sectional view illustrating a semiconductor device of FIG. 1 taken along line I-I′.

FIG. 3 is a schematic circuit diagram corresponding to a semiconductor device of FIG. 1.

FIG. 4A is a view schematically illustrating a first write operation of a semiconductor device according to an embodiment of the present disclosure.

FIG. 4B is an energy band diagram of first and second oxide channel layers, corresponding to FIG. 4A.

FIG. 5A is a view schematically illustrating a second write operation of a semiconductor device according to an embodiment of the present disclosure.

FIG. 5B is an energy band diagram of first and second oxide channel layers, corresponding to FIG. 5A.

FIGS. 6 to 12 are cross-sectional views schematically illustrating a method of fabricating a semiconductor device according to an embodiment of the present disclosure.

FIGS. 13 and 14 are cross-sectional views schematically illustrating a method of fabricating a semiconductor device according to another embodiment of the present disclosure.

### DETAILED DESCRIPTION

Hereinafter, embodiments of the present disclosure will be described in detail with reference to the accompanying drawings. In the drawings, in order to clearly express the components of each device, the sizes of the components, such as width and thickness of the components, are enlarged. The terms used herein may correspond to words selected in consideration of their functions in the embodiments, and the meanings of the terms may be construed to be different according to the ordinary skill in the art to which the embodiments belong. If expressly defined in detail, the terms may be construed according to the definitions. Unless otherwise defined, the terms (including technical and scientific terms) used herein have the same meaning as commonly understood by one of ordinary skill in the art to which the embodiments belong.

In addition, expression of a singular form of a word should be understood to include the plural forms of the word unless clearly used otherwise in the context. It will be understood that the terms “comprise”, “include”, or “have” are intended to specify the presence of a feature, a number, a step, an operation, a component, an element, a part, or combinations thereof, but not used to preclude the presence or possibility of addition one or more other features, numbers, steps, operations, components, elements, parts, or combinations thereof.

Further, in performing a method or a fabricating method, each process constituting the method can take place differently from the stipulated order unless a specific sequence is described explicitly in the context. In other words, each process may be performed in the same manner as stated order, and may be performed substantially at the same time. Also, at least a part of each of the above processes may be performed in a reversed order.

In this specification, a source electrode layer and a drain electrode layer may be relative terms. That is, depending on the circuit configuration of a ferroelectric field effect transistor, the source electrode layer and the drain electrode layer may be functionally interchanged with each other. As an example, depending on the circuit configuration, the source electrode layer may function as a drain electrode, and the drain electrode layer may function as a source electrode.

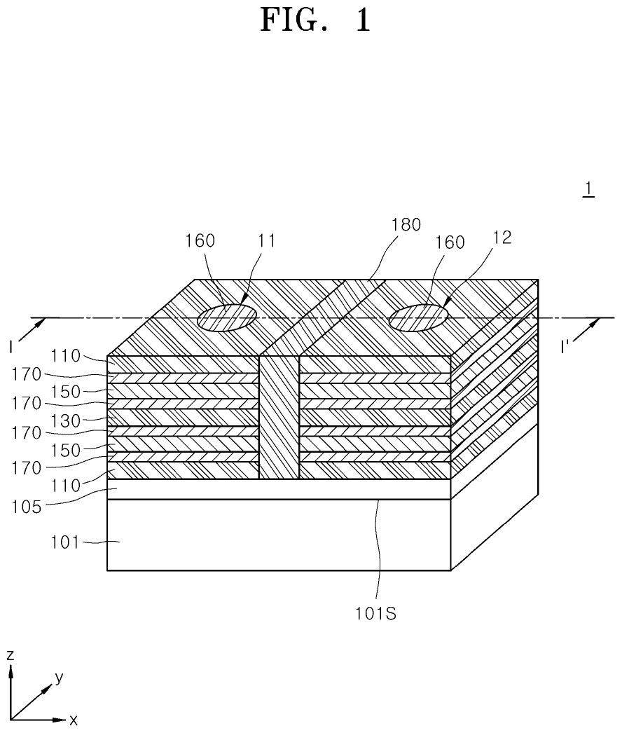

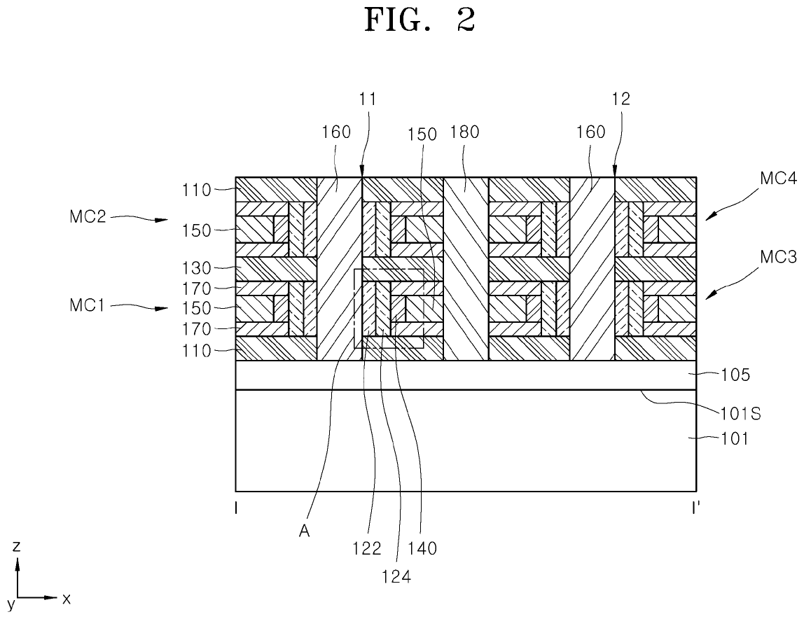

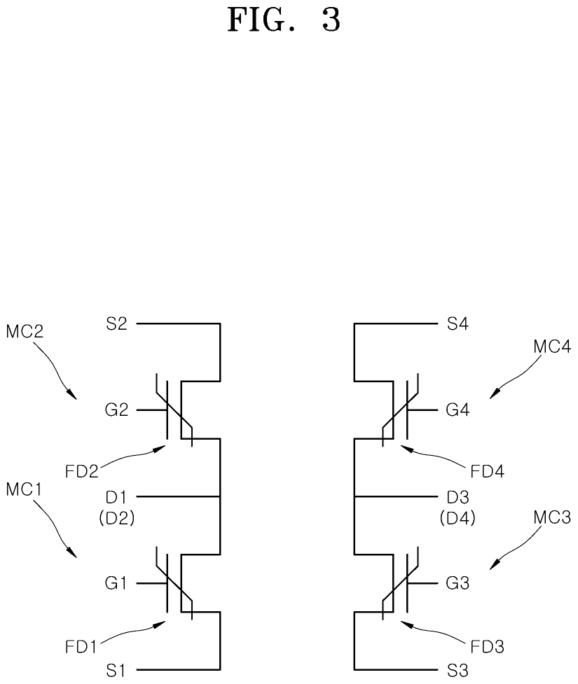

FIG. 1 is a perspective view schematically illustrating a semiconductor device according to an embodiment of the present disclosure. FIG. 2 is a cross-sectional view illustrating a semiconductor device of FIG. 1 taken along line I-I′. FIG. 3 is a schematic circuit diagram corresponding to a semiconductor device of FIG. 1.

Referring to FIG. 2, a semiconductor device 1 may include first to fourth memory cells MC1, MC2, MC3, and MC4 arranged over a substrate 101. Each of the first to fourth memory cells MC1, MC2, MC3, and MC4 may include a nonvolatile memory element. Each of the first to fourth memory cells MC1, MC2, MC3, and MC4 may include, for example, a ferroelectric field effect transistor.

Referring to FIG. 3, the first memory cell MC1 may include a first ferroelectric layer FD1 and a first gate electrode G1 between a first source electrode S1 and a first drain electrode D1. Through a write voltage applied to the first gate electrode G1, remanent polarization of a predetermined orientation may be written in the first ferroelectric layer FD1 as signal information. The second memory cell MC2 may include a second ferroelectric layer FD2 and a second gate electrode G2 for storing signal information between a second source electrode S2 and a second drain electrode D2. In this case, the first and second memory cells MC1 and MC2 may share the drain electrode D1/D2. That is, the first drain electrode D1 of the first memory cell MC1 and the second drain electrode D2 of the second memory cell MC2 may be the same drain electrode.

Similarly, in FIG. 3, the third memory cell MC3 may include a third ferroelectric layer FD3 and a third gate electrode G3 for storing signal information between a third source electrode S3 and a third drain electrode D3. The fourth memory cell MC4 may include a fourth ferroelectric layer FD4 and a fourth gate electrode G4 for storing signal information between a fourth source electrode S4 and a fourth drain electrode D4. In this case, the third and fourth memory cells MC3 and MC4 may share the drain electrode D3/D4. That is, the third drain electrode D3 of the third memory cell MC3 and the fourth drain electrode D4 of the fourth memory cell MC4 may be the same drain electrode.

Referring back to FIG. 2, the second memory cell MC2 and the fourth memory cell MC4 may be disposed over the first memory cell MC1 and the third memory cell MC3, respectively. The first memory cell MC1 and the third memory cell MC3, which are disposed to be adjacent to each other on a plane substantially parallel to a surface 101S of the substrate 101, may be electrically separated from each other by a cell isolation structure 180. Similarly, the second memory cell MC2 and the fourth memory cell MC4, which are disposed to be adjacent to each other on a plane substantially parallel to the surface 101S of the substrate 101, may be electrically separated from each other by the cell isolation structure 180. Referring to FIGS. 1 and 2 together, the cell isolation structure 180 may be an insulating barrier structure that extends in a direction (e.g., the z-direction) substantially perpendicular to the surface 101S of the substrate 101 and in a direction (e.g., the y-direction) substantially parallel to the surface 101S of the substrate 101. The cell isolation structure 180 may include, for example, oxide, nitride, oxynitride, or a combination thereof. In an embodiment, the cell isolation structure 180 may include a silicon nitride layer or a metal nitride layer.

Referring to FIGS. 1 and 2 together, the first to fourth memory cells MC1, MC2, MC3, and MC4 may have substantially the same configurations relative to each other in terms of structure, but in terms of electrical operation, each memory cell may operate independently of each other, consistent with the circuit diagram of FIG. 3. In an embodiment, the first and second memory cells MC1 and MC2 may be disposed to share a drain electrode layer 130 in terms of structure, but may operate independently of each other in terms of electricity. Similarly, the third and fourth memory cells MC3 and MC4 may be disposed to share the drain electrode layer 130 in terms of structure, but may operate independently of each other in terms of electricity.

Meanwhile, although FIG. 2 illustrates four memory cells MC1, M2, MC3, and MC4 disposed over the substrate 101, inventive concept disclosed herein may not be limited to this configuration. In other embodiments, a semiconductor device 1 may include various numbers of memory cells disposed over the substrate 101.

Referring to FIGS. 1 and 2 together, each of the first to fourth memory cells MC1, M2, MC3, and MC4 may include a source electrode layer 110 and the drain electrode layer 130, separated by the cell isolation structure 180 and disposed over the substrate 101 to be spaced apart from each other in the z-direction; first and second oxide channel layers 122 and 124 disposed between the source electrode layer 110 and the drain electrode layer 130 in the z-direction; a ferroelectric layer 140 disposed to be adjacent to the first and second oxide channel layers 122 and 124; and a gate electrode layer 150 disposed to be in contact with the ferroelectric layer 140. In addition, each of the first to fourth memory cells MC1, MC2, MC3, and MC4 may include first and second channel passivation layers 160 and 170 that are disposed to cover portions of the first and second oxide channel layers 122 and 124 over the substrate 101.

Referring to FIGS. 1 and 2 together, the substrate 101 may be provided. The substrate 101 may include a semiconductor material. Specifically, the semiconductor material may include silicon (Si), germanium (Ge), gallium arsenide (GaAs), or the like. The substrate 101 may be doped with an n-type dopant or a p-type dopant to have predetermined conductivity.

Although not illustrated in FIGS. 1 and 2, the substrate 101 may include integrated circuits. The integrated circuits may include a cell driver circuit that drives and controls the first to fourth memory cells MC1, MC2, MC3, and MC4. The integrated circuits may include an electronic device, such as a diode, and a transistor.

A base insulation layer 105 may be disposed on the substrate 101. The base insulation layer 105 may include, for example, oxide, nitride, oxynitride, or a combination of two or more thereof. Although not illustrated in FIGS. 1 and 2, at least one conductive layer may be disposed inside the base insulation layer 105. The at least one conductive layer may function as a wiring that connects different integrated circuits of the substrate 101 to each other or a wiring that connects the integrated circuits and the first to fourth memory cells MC1, MC2, MC3, and MC4.

The source electrode layer 110 may be disposed on the base insulation layer 105. The source electrode layer 110 may include a conductive material. The conductive material may include, for example, doped semiconductor, metal, conductive metal nitride, conductive metal carbide, conductive metal silicide, or conductive metal oxide. The conductive material may include, for example, n-type doped silicon (Si), platinum (Pt), gold (Au), palladium (Pd), molybdenum (Mo), nickel (Ni), tungsten (W), titanium (Ti), copper (Cu), aluminum (Al), ruthenium (Ru), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof.

Referring to FIGS. 1 and 2, the drain electrode layer 130 may be disposed to be spaced apart from the source electrode layer 110 in a direction (e.g., the z-direction) substantially perpendicular to the surface 101S of the substrate 101. The drain electrode layer 130 may be made of substantially the same material as the source electrode layer 110.

Referring to FIG. 2, the first oxide channel layer 122 may be disposed between the source electrode layer 110 and the drain electrode layer 130. The first oxide channel layer 122 may be disposed to extend in the direction (e.g., the z-direction) substantially perpendicular to the surface 101S of the substrate 101. Accordingly, the first oxide channel layer 122 may be disposed to contact the source electrode layer 110 and the drain electrode layer 130. The first oxide channel layer 122 may include electrons that move with a predetermined electron mobility along an applied electric field when the electric field is applied between the source electrode layer 110 and the drain electrode layer 130.

The first oxide channel layer 122 may include metal oxide. The metal oxide may include, for example, gallium oxide, indium gallium oxide, indium selenium oxide, indium magnesium oxide, indium gallium zinc oxide, indium tin gallium zinc oxide, indium silver oxide, or a combination of two or more thereof.

Referring to FIG. 2, the second oxide channel layer 124 may be disposed to be adjacent to the first oxide channel layer 122. In an embodiment, the second oxide channel layer 124 may be disposed to be in contact with the first oxide channel layer 122. The second oxide channel layer 124 may be disposed to extend in the direction (e.g., the z-direction) substantially perpendicular to the surface 101S of the substrate 101 and to extend between the source electrode layer 110 and the drain electrode layer 130.

The second oxide channel layer 124 may be disposed to contact the source electrode layer 110 and the drain electrode layer 130. The second oxide channel layer 124 may include electrons that move with a predetermined electron mobility along an applied electric field when the electric field is applied between the source electrode layer 110 and the drain electrode layer 130.

The second oxide channel layer 124 may include metal oxide. The metal oxide may include, for example, gallium oxide, indium gallium oxide, indium selenium oxide, indium magnesium oxide, indium gallium zinc oxide, indium tin gallium zinc oxide, indium silver oxide, or a combination of two or more thereof. The second oxide channel layer 124 may have a band gap energy different from a band gap energy of the first oxide channel layer 122. In an embodiment, the second oxide channel layer 124 may have a band gap energy smaller than the band gap energy of the first oxide channel layer 122.

Referring to FIG. 2, the ferroelectric layer 140 may be disposed to be adjacent to the first and second oxide channel layers 122 and 124, and to be arranged between the source electrode layer 110 and the drain electrode layer 130 in the z-direction. Specifically, the ferroelectric layer 140 may be disposed on a sidewall of the second oxide channel layer 124. The ferroelectric layer 140 may have a pair of remanent polarization states having different orientations. The ferroelectric layer 140 may be disposed to contact the second oxide channel layer 124. The ferroelectric layer 140 may be disposed to be spaced apart from the source electrode layer 110 and the drain electrode layer 130 in the z-direction. The ferroelectric layer 140 may include metal oxide. For example, the metal oxide may include hafnium oxide, zirconium oxide, hafnium zirconium oxide, or a combination of two or more thereof.

The gate electrode layer 150 may be disposed on a sidewall of the ferroelectric layer 140. The gate electrode layer 150 may be disposed to be spaced apart from the source electrode layer 110 and the drain electrode layer 130 in the z-direction. The gate electrode layer 150 may include a conductive material. The conductive material may include, for example, doped semiconductor, metal, conductive metal nitride, conductive metal carbide, conductive metal silicide, or conductive metal oxide. The conductive material may include, for example, n-type doped silicon (Si), platinum (Pt), gold (Au), palladium (Pd), molybdenum (Mo), nickel (Ni), tungsten (W), titanium (Ti), copper (Cu), aluminum (Al), ruthenium (Ru), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof.

According to the polarity of the write voltage applied between the gate electrode layer 150 and the first and second oxide channel layers 122 and 124, a pair of remanent polarization states having different orientations may be written in the ferroelectric layer 140. The remanent polarization states may be stored as signal information in the ferroelectric layer 140.

Referring to FIGS. 1 and 2 again, the first channel passivation layer 160 may be disposed, over the substrate 101, to cover the side surface of the first oxide channel layer 122. The first channel passivation layer 160 may extend in a direction that is substantially perpendicular to the surface 101S of the substrate 101. The first channel passivation layer 160 may be a pillar-type structure. The first channel passivation layer 160 may be disposed to passivate the side surfaces of the source electrode layer 110, the first oxide channel layer 122, and the drain electrode layer 130.

In addition, the second channel passivation layer 170 may be disposed, over the substrate 101, to cover portions of the side surface of the second oxide channel layer 124. The second channel passivation layer 170 may be disposed to shield portions of the second oxide channel layer 124, which extends between the source electrode layer 110 and the drain electrode layer 130. The second channel passivation layer 170 may be disposed to contact the second oxide channel layer 124 in a lateral or horizontal direction (e.g., the y-direction) that is substantially parallel to the surface 101S of the substrate 101.

Each of the first and second channel passivation layers 160 and 170 may include an insulating material. In an embodiment, each of the first and second channel passivation layers 160 and 170 may include nitride. The nitride may be, for example, silicon nitride or metal nitride. The nitride may inhibit diffusion of chemicals containing hydrogen (H) or fluorine (F). Accordingly, the first and second channel passivation layers 160 and 170 may block some undesired chemicals from flowing into the first and second oxide channel layers 122 and 124 from the outside of the first and second oxide channel layers 122 and 124. As a result, it is possible to reduce deterioration of the electrical properties of the first and second oxide channel layers 122 and 124.

Referring to FIGS. 1 and 2 again, the first channel passivation layer 160 may be a structure extending in a direction (e.g., the z-direction) that is substantially perpendicular to the surface 101S of the substrate 101 on the base insulation layer 105. The first channel passivation layer 160 may be formed to fill holes 11 and 12, which are formed to penetrate the first to fourth memory cells MC1, MC2, MC3, and MC4 in a direction (e.g., the z-direction) substantially perpendicular to the surface 101S of the substrate 101.

The first oxide channel layer 122, the source electrode layer 110, and the drain electrode layer 130 may be disposed to surround a section of the outer peripheral surface of the first channel passivation layer 160. The second oxide channel layer 124 may be disposed to surround the first channel passivation layer 160 while disposed on the side surface of the first oxide channel layer 122.

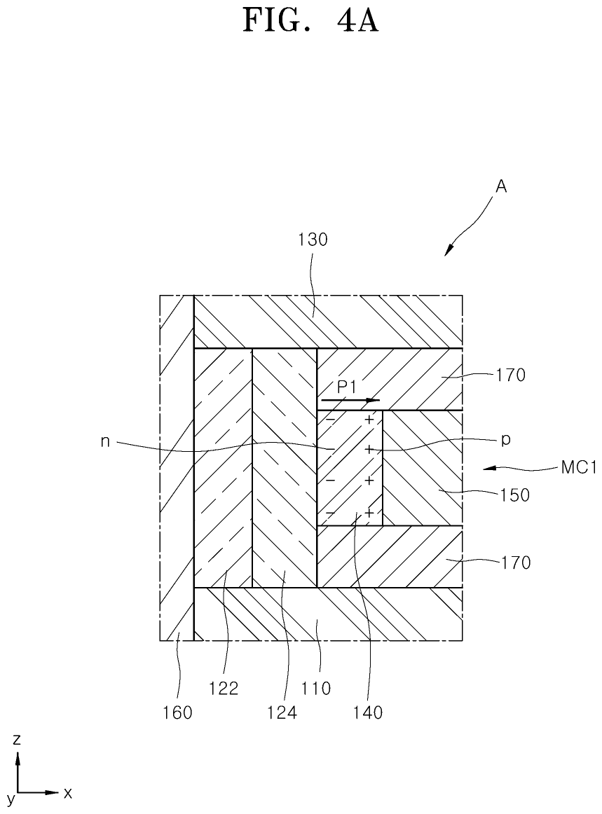

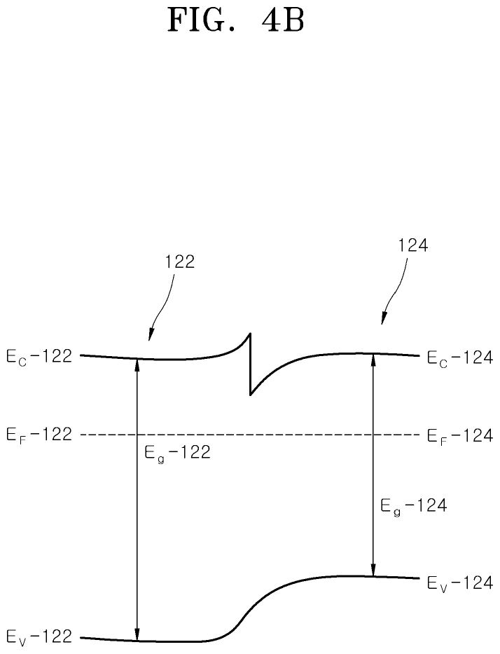

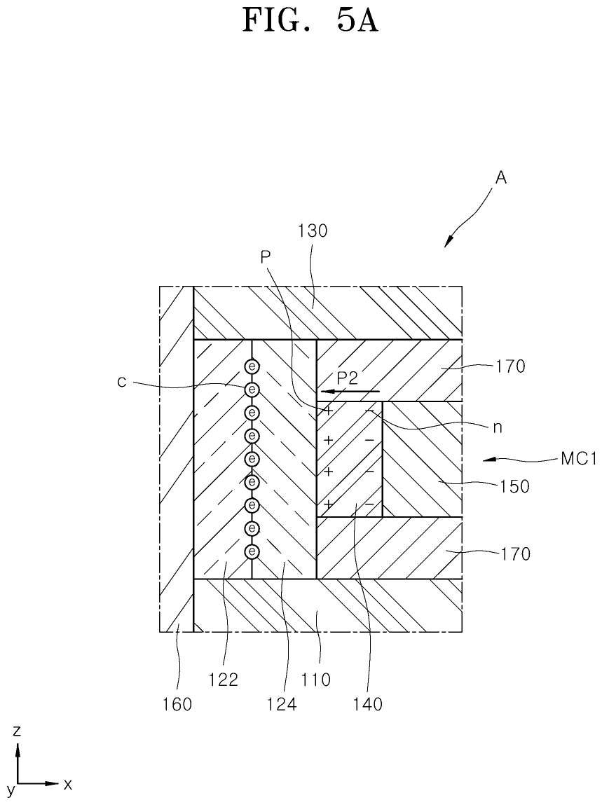

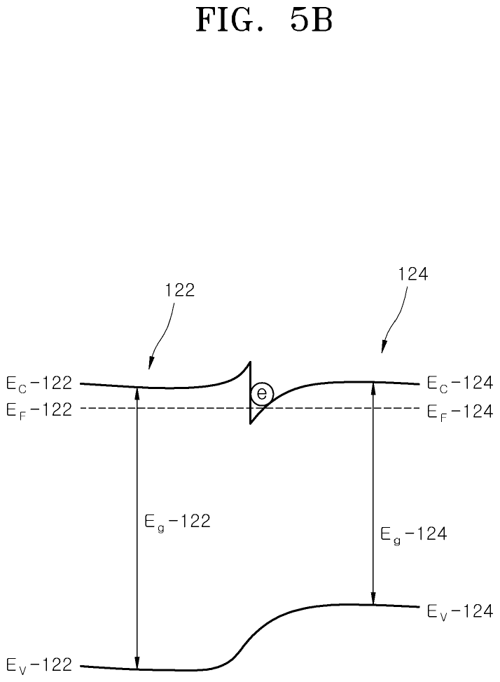

FIG. 4A is a view schematically illustrating a first write operation of a semiconductor device according to an embodiment of the present disclosure. FIG. 4B is an energy band diagram of first and second oxide channel layers, corresponding to FIG. 4A. FIG. 5A is a view schematically illustrating a second write operation of the semiconductor device according to an embodiment of the present disclosure. FIG. 5B is an energy band diagram of the first and second oxide channel layers, corresponding to FIG. 5A. FIGS. 4A and 5A may be partially enlarged views of region ‘A’ of FIG. 2. The first and second write operations of a semiconductor device 1 may be described using the first memory cell MC1 as an example.

Referring to FIG. 4A, a first write operation on the first memory cell MC1 may be performed. The first write operation may be performed by grounding the first and second oxide channel layers 122 and 124 and applying a first write voltage having a negative polarity to the gate electrode layer 150. The first write voltage may align the polarization of the ferroelectric layer 140 in a first direction. The first direction may be a direction from the second oxide channel layer 124 toward the gate electrode layer 150.

After the first write voltage is removed, the polarization of the ferroelectric layer 140 may remain as first remanent polarization P1 aligned in the first direction inside the ferroelectric layer 140, so that the ferroelectric layer 140 may store the first remanent polarization P1 as first signal information. The first remanent polarization P1 may dispose negative charges n in the inner region of the ferroelectric layer 140, adjacent to the second oxide channel layer 124, and may dispose positive charges p in the inner region of the ferroelectric layer 140, adjacent to the gate electrode layer 150.

After the first write operation is performed, the energy states of the first and second oxide channel layers 122 and 124 may be understood with reference to FIG. 4B. That is, FIG. 4B may be an energy band diagram of the first and second oxide channel layers 122 and 124 after the remanent polarization P1 is formed in the ferroelectric layer 140. Because the band gap energies Eg-122 and Eg-124 of the first and second oxide channel layers 122 and 124 are different from each other, band bending may occur at an interface between the first and second oxide channel layers 122 and 124. In FIG. 4B, the Fermi energy levels E_{F}-122 and E_{F}-124 of the first and second oxide channel layers 122 and 124 may be located between conduction bands and valence bands of the first and second oxide channels 122 and 124, respectively. In FIG. 4B, ‘Ec-122’ and ‘Ev-122’ may refer to the conduction band energy and the valence band energy of the first oxide channel layer 122, respectively, and ‘Ec-124’ and ‘Ev-124’ may refer to the conduction band energy and the valence band energy of the second oxide channel layer 124, respectively.

Referring to FIG. 5A, a second write operation on the first memory cell MC1 may be performed. The second write operation may be performed by grounding the first and second oxide channel layers 122 and 124, and applying a second write voltage having a positive polarity to the gate electrode layer 150. The second write voltage may align the polarization of the ferroelectric layer 140 in a second direction. The second direction may be a direction from the gate electrode layer 150 toward the second oxide channel layer 124.

After the second write voltage is removed, the polarization of the ferroelectric layer 140 may remain as second remanent polarization P2 aligned in the second direction inside the ferroelectric layer 140, so that the ferroelectric layer 140 may store the second remanent polarization P2 as second signal information. The second remanent polarization P2 may dispose positive charges p in the inner region of the ferroelectric layer 140, adjacent to the second oxide channel layer 124, and may dispose negative charges n in the inner region of the ferroelectric layer 140, adjacent to the gate electrode layer 150. In addition, after the second write operation is performed, electrons c may accumulate at the interface between the first and second oxide channel layers 122 and 124.

After the second write operation is performed, the energy states of the first and second oxide channel layers 122 and 124 may be understood with reference to FIG. 5B. That is, FIG. 5B may be an energy band diagram of the first and second oxide channel layers 122 and 124 after the remanent polarization P2 is formed in the ferroelectric layer 140. The Fermi energy levels E_{F}-122 and E_{F}-124 of the first and second oxide channel layers 122 and 124 may be higher than the conduction band energy of the second oxide channel layer 124 at the interface between the first and second oxide channels 122 and 124. Accordingly, at the interface between the first and second oxide channel layers 122 and 124, electrons c, which are conductive carriers, may accumulate.

Meanwhile, a read operation on the first memory cell MC1 may be performed by applying a read voltage having a positive polarity to the gate electrode layer 150 and applying an operation voltage between the source electrode layer 110 and the drain electrode layer 130 to determine the current flowing between the source electrode layer 110 and the drain electrode layer 130. In an example, an absolute value of the read voltage may be low enough so that the first and second signal information does not change. In some embodiments, the read voltage may be 0 V.

When the ferroelectric layer 140 of the first memory cell MC1 stores the second signal information described with reference to FIGS. 5A and 5B, during the read operation, the electrons accumulated at the interface between the first and second oxide channel layers 122 and 124 may conduct between the source electrode layer 110 and the drain electrode layer 130 to increase the density of a channel current. On the other hand, when the ferroelectric layer 140 of the first memory cell MC1 stores the first signal information described with reference to FIGS. 4A and 4B, the channel current conducting between the source electrode layer 110 and the drain electrode layer 130 may be lower. As an example, a sufficiently low channel current may correspond to the magnitude of a leakage current.

Accordingly, when a read operation is performed on the first memory cell MC1, the density of the channel current may increase due to the electrons accumulated at the interface of the first and second oxide channel layers 122 and 124, so that the second signal information may be more easily identified compared to the first signal information.

According to an embodiment of the present disclosure, the ferroelectric layer 140 may be formed on the side surface of the second oxide channel layer 124. The ferroelectric layer 140, which includes metal oxide, may form an interface with the second oxide channel layer 124, so that it is possible to prevent an unwanted insulation layer from being formed at the interface. In the conventional case, however, when a ferroelectric layer including metal oxide is directly formed on a semiconductor substrate, an interfacial insulation layer having a low dielectric constant may be formed at an interface between the semiconductor substrate and the ferroelectric layer by oxidation of the semiconductor substrate. The interfacial insulation layer may be connected in series to the ferroelectric layer to form a low dielectric layer that is thinner than the ferroelectric layer. Accordingly, when a gate voltage is applied between the semiconductor substrate and a gate electrode layer disposed on the ferroelectric layer for the operation of a transistor, an electric field is concentrated on the interfacial insulation layer rather than the ferroelectric layer, and as a result the endurance of the transistor may be reduced or deteriorate may occur. On the other hand, according to embodiments of the present disclosure, the interfacial insulation layer may be prevented from forming at the interface between the ferroelectric layer 140 and the second oxide channel layer 124, thereby reducing deterioration in endurance of the semiconductor device.

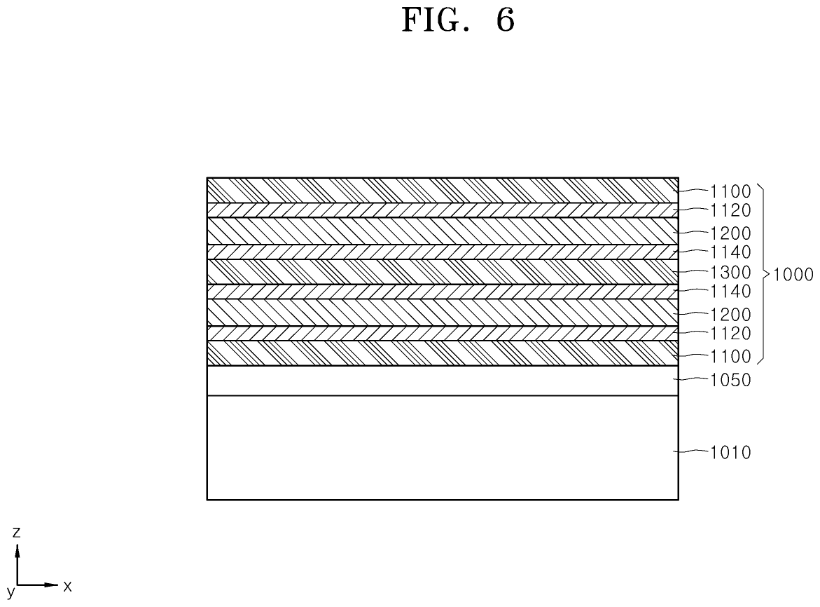

FIGS. 6 to 12 are cross-sectional views schematically illustrating a method of fabricating a semiconductor device according to an embodiment of the present disclosure. A method of fabricating a semiconductor device described with reference to FIGS. 6 to 12 may be applied to the method of fabricating the semiconductor device 1 described above with reference to FIGS. 1 and 2.

Referring to FIG. 6, a substrate 1010 may be provided. The substrate 1010 may include a semiconductor material. Specifically, the semiconductor material may include silicon (Si), germanium (Ge), gallium arsenide (GaAs), or the like. The substrate 1010 may be doped with an n-type dopant or a p-type dopant to have predetermined conductivity.

Although not illustrated in FIG. 6, integrated circuits may be formed in the substrate 1010. The integrated circuits may include cell driver circuits for driving and controlling memory cells formed over the substrate 1010. The integrated circuits may include electronic devices such as diodes and transistors.

A base insulation layer 1050 may be formed on the substrate 1010. The base insulation layer 1050 may include, for example, oxide, nitride, oxynitride, or a combination of two or more thereof. Although not illustrated in FIG. 6, at least one conductive layer may be formed in the base insulation layer 1050. The conductive layer may function as a wiring for connecting different integrated circuits to each other, or for connecting the integrated circuits and other memory cells to each other.

A stack structure 1000 may be formed on the base insulation layer 1050. The stack structure 1000 may include a source electrode material layer 1100, a first passivation material layer 1120, a gate electrode material layer 1200, a second passivation material layer 1140, a drain electrode material layer 1300, another second passivation material layer 1140, another gate electrode material layer 1200, another first passivation material layer 1120, and another source electrode material layer 1100, which are sequentially stacked on the base insulation layer 1050.

Each of the source electrode material layers 1100, the gate electrode material layers 1200, and the drain electrode material layers 1300 may include a conductive material. The conductive material may include, for example, n-type doped silicon (Si), platinum (Pt), gold (Au), palladium (Pd), molybdenum (Mo), nickel (Ni), tungsten (W), titanium (Ti), copper (Cu), aluminum (Al), ruthenium (Ru), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof. Each of the source electrode material layers 1100, the gate electrode material layers 1200, and the drain electrode material layers 1300 may be formed using, for example, a chemical vapor deposition method, an atomic layer deposition method, or a sputtering method.

Each of the first and second passivation material layers 1120 and 1140 may include nitride. The nitride may include, for example, silicon nitride or metal nitride. Each of the first and second passivation material layers 1120 and 1140 may be formed using, for example, a chemical vapor deposition method, an atomic layer deposition method, or a sputtering method. Each of the first and second passivation material layers 1120 and 1140 may include etch selectivity with respect to the source electrode material layers 1100, the gate electrode material layers 1200, and the drain electrode material layers 1300.

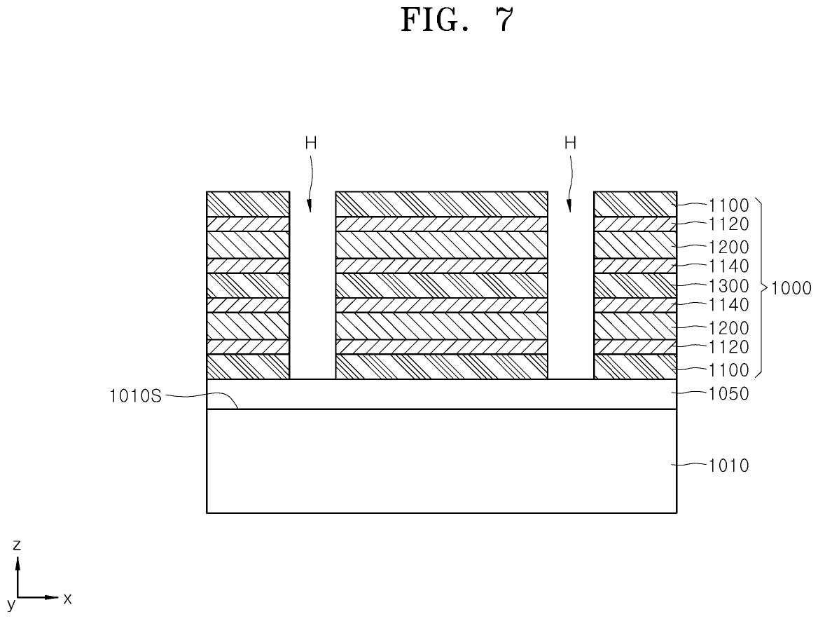

Referring to FIG. 7, hole patterns H may be formed to penetrate the stack structure 1000 over the substrate 101. The hole patterns H may be formed by selectively etching the stack structure 1000. The hole patterns H may be formed in a direction that is substantially perpendicular to a surface 1010S of the substrate 101, and may expose the base insulation layer 1050.

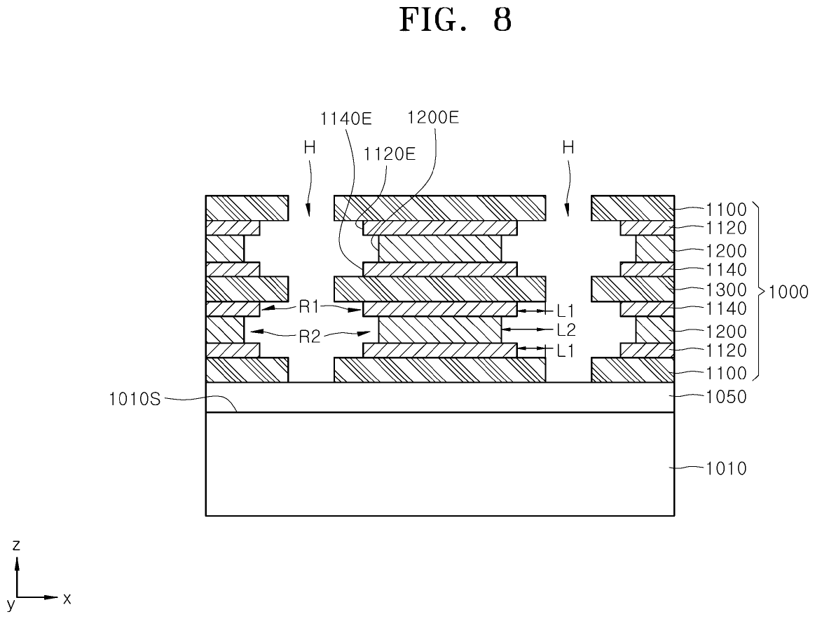

Referring to FIG. 8, the first and second passivation material layers 1120 and 1140 may be selectively recessed inside the hole patterns H to form first recess spaces R1. In addition, the gate electrode material layers 1200 may be selectively recessed inside the hole patterns H to form second recess spaces R2.

In an embodiment, the process of forming the first recess spaces R1 may include a process of etching the first and second passivation material layers 1120 and 1140 in an inner direction that is substantially parallel to the surface 1010S of the substrate 1010 (e.g., the x-direction). In addition, the process of forming the second recess spaces R2 may include a process of etching the gate electrode material layers 1200 in the inner direction (e.g., the x-direction). As a result, in the inner direction (e.g., x-direction), the edges 1200E of the etched gate electrode material layers 1200 may be located farther from the center of the hole pattern H than the edges 1120E and 1140E of the etched first and second passivation material layers 1120 and 1140. That is, the second recess spaces R2 may extend beyond the first recess spaces R1 in the inner direction.

Referring to FIG. 8, the second recess spaces R2 may extend further in the lateral direction (e.g., the x-direction) than the first recess spaces R1. That is, the gate electrode material layers 1200 may be more recessed in the lateral direction (e.g., the x-direction) than the first and second passivation material layers 1120 and 1140. In this case, the first and second passivation material layers 1120 and 1140 may be recessed by substantially the same amount. Accordingly, the edges 1120E and 1140E of the first and second passivation material layers 1120 and 1140 may overlap with each other in a direction (i.e., the z-direction) that is substantially perpendicular to the surface 1010S of the substrate 1010.

In an embodiment, the first and second recess spaces R1 and R2 may be formed by injecting an etchant having etch selectivity into the hole patterns H to selectively etch the first and second passivation material layers 1120 and 1140 and the gate electrode material layers 1200.

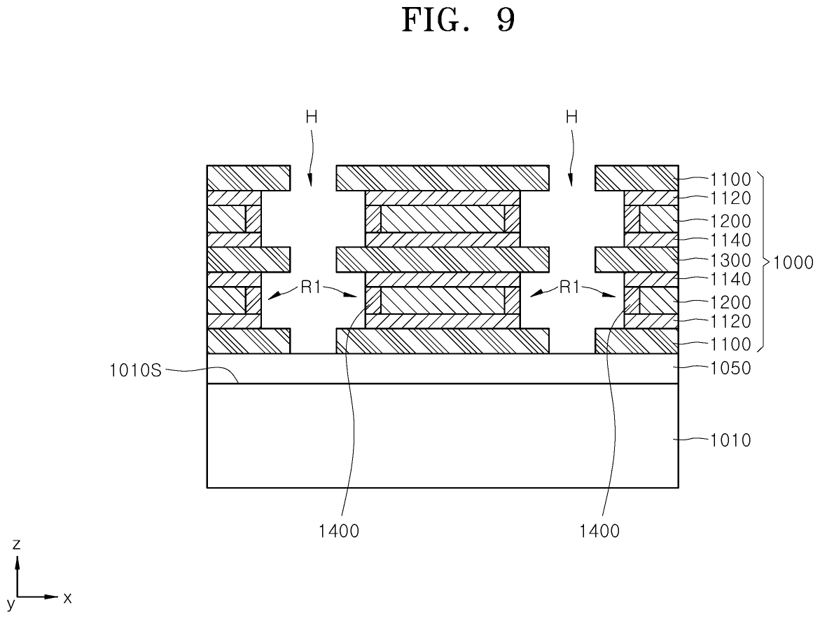

Referring to FIG. 9, a ferroelectric layer 1400 may be formed in the second recess spaces R2. In an embodiment, the ferroelectric layer 1400 may be formed to fill the second recess spaces R2. The ferroelectric layer 1400 may include ferroelectric metal oxide. As an example, the ferroelectric metal oxide may include hafnium oxide, zirconium oxide, hafnium zirconium oxide, or a combination of two or more thereof. The ferroelectric layer 1400 may be formed using, for example, a chemical vapor deposition method, an atomic layer deposition method, or the like.

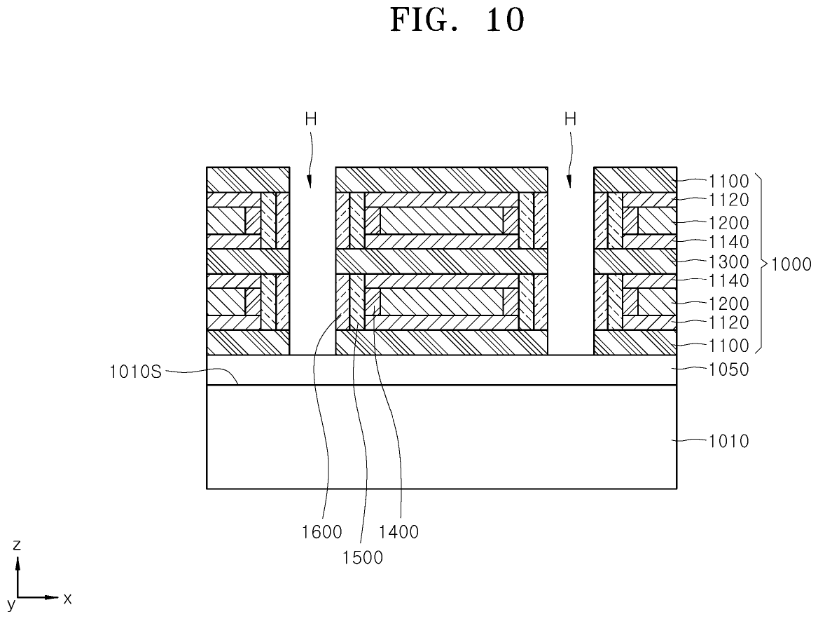

Referring to FIG. 10, first channel material layers 1500 may be formed in the first recess spaces R1, and second channel material layers 1600 may be formed on the side surfaces of the first channel material layers 1500. The first channel material layers 1500 may be formed to contact the first and second passivation material layers 1120 and 1140 and the ferroelectric layers 1400 in a direction (e.g., the x-direction) that is substantially parallel to the surface 1010S of the substrate 1010. The second channel material layers 1600 may be formed to contact the first channel material layers 1500. In an embodiment, the first recess spaces R1 may be filled by the first and second channel material layers 1500 and 1600.

Each of the first and second channel material layers 1500 and 1600 may include metal oxide. As an example, the metal oxide may include gallium oxide, indium gallium oxide, indium selenium oxide, indium magnesium oxide, indium gallium zinc oxide, indium tin gallium zinc oxide, indium silver oxide, or a combination of two or more thereof. The first and second channel material layers 1500 and 1600 may be formed using, for example, a chemical vapor deposition method or an atomic layer deposition method.

The magnitude of the band gap energy of the first channel material layer 1500 may be different from the magnitude of the band gap energy of the second channel material layer 1600. In an embodiment, the magnitude of the band gap energy of the first channel material layer 1500 may be smaller than the magnitude of the band gap energy of the second channel material layer 1600.

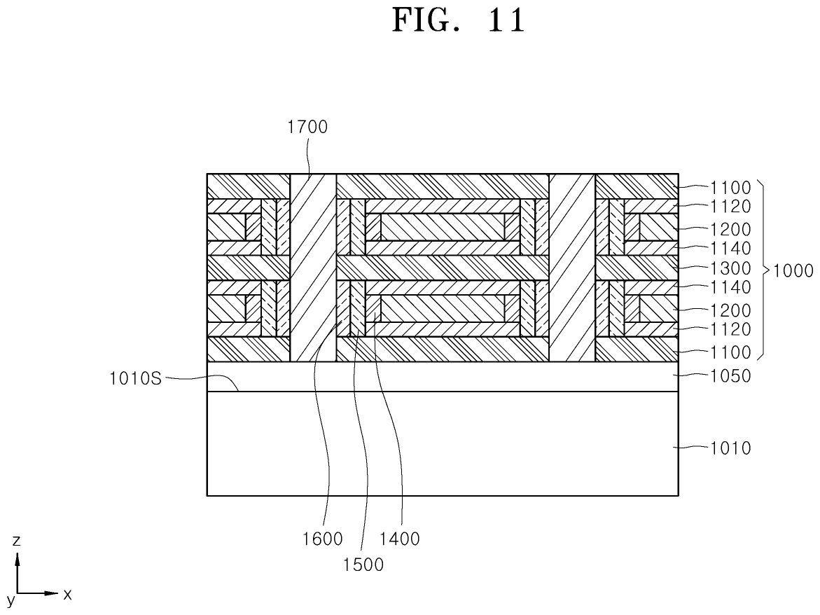

Referring to FIG. 11, third passivation material layers 1700 may be formed inside the hole patterns H on the base insulation layer 1050. The third passivation material layers 1700 may be formed to cover at least the second channel material layers 1600. Specifically, the third passivation material layers 1700 may be formed to cover the side surfaces of the source electrode material layers 1100, the drain electrode material layers 1300, and the second channel material layers 1600. The third passivation material layers 1700 may include nitride. The nitride may include, for example, silicon nitride or metal nitride.

In an embodiment, the third passivation material layers 1700 may be formed by forming a nitride structure to fill the hole patterns (H of FIG. 10). The third passivation material layers 1700 may be formed using, for example, a chemical vapor deposition method, an atomic layer deposition method, or a sputtering method.

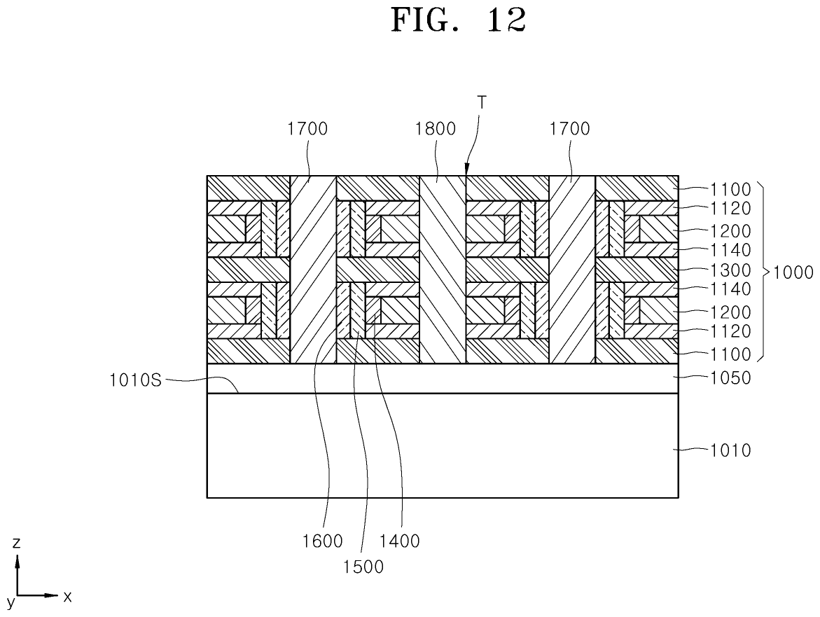

Referring to FIG. 12, a trench pattern T located between adjacent third passivation material layers 1700 may be formed. The trench pattern T may extend in a direction (e.g., the z-direction) that is substantially perpendicular to the surface 1010S of the substrate 1010, as well as in a direction (e.g., the y-direction) that is substantially parallel to the surface 1010S of the substrate 1010. After formation, the trench pattern T may be filled with a conductive material to form a cell isolation structure 1800.

The cell isolation structure 1800 may include an insulating material. As an example, the insulating material may include oxide, nitride, oxynitride, or a combination of two or more thereof. In an embodiment, the cell isolation structure 1800 may include a silicon nitride layer or a metal nitride layer. Through the above-described processes, a semiconductor device according to an embodiment of the present disclosure may be fabricated.

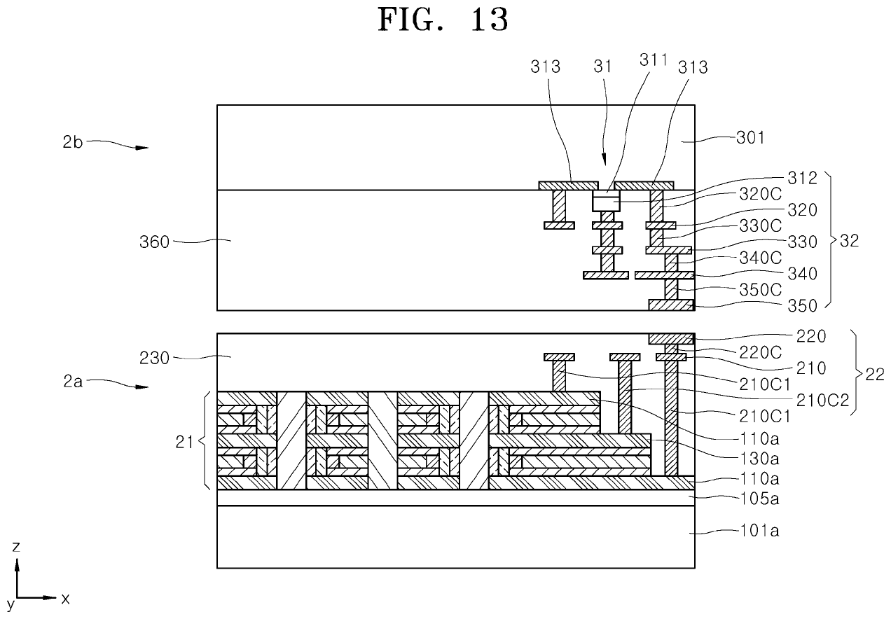

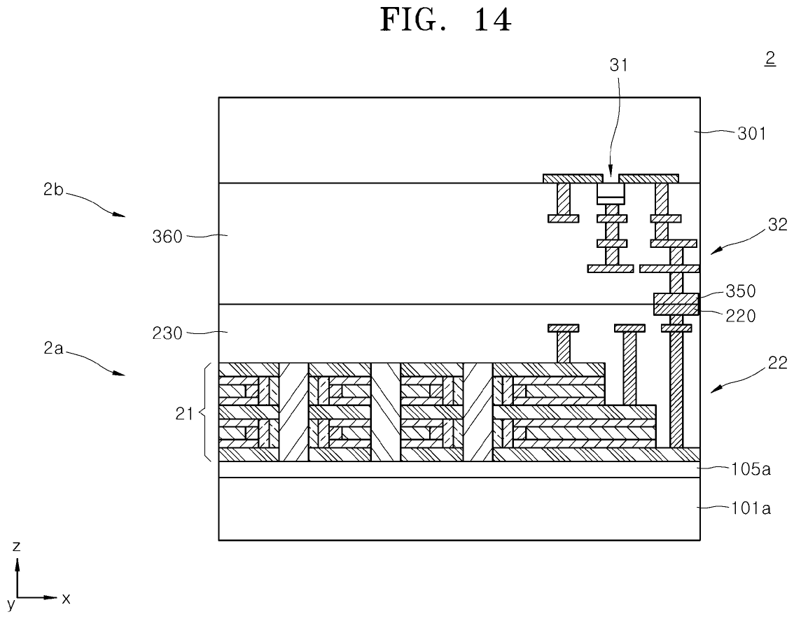

FIGS. 13 and 14 are cross-sectional views schematically illustrating a method of fabricating a semiconductor device according to another embodiment of the present disclosure. Referring to FIG. 13, a cell wafer 2a and a driver circuit wafer 2b may be fabricated.

The cell wafer 2a may include a substrate 101a, a base insulation layer 105a, a cell structure 21, a cell wiring structure 22, and a cell capping insulation layer 230. The configuration including the substrate 101a, the base insulation layer 105a, and the cell structure 21 may be substantially the same as the configuration of a semiconductor device 1 described above with reference to FIGS. 1 and 2. However, the substrate 101a might not include a cell driver circuit for driving and controlling the cell structure 21. The cell driver circuit may be formed in the driver circuit wafer 2b.

The cell wiring structure 22 may be formed over the cell structure 21. The cell wiring structure 22 may include at least one cell circuit pattern layer 210 electrically connected to a source electrode layer 110a and a drain electrode layer 130a. In addition, the cell wiring structure 22 may include source contact layer 210C1 and a drain contact layer 210C2 that electrically connect the at least one cell circuit pattern layer 210 to the source electrode layer 110a and the drain electrode layer 130a, respectively. Although not illustrated, the at least one cell circuit pattern layer 210 may be electrically connected to a gate electrode layer of the cell structure 21 through a gate contact layer.

In addition, the cell wiring structure 22 may include a cell bonding pad 220 electrically connected to the at least one cell circuit pattern layer 210. The cell bonding pad 220 may be electrically connected to the at least one cell circuit pattern layer 210 through a cell pad contact layer 220C. The cell capping insulation layer 230 may be formed to cover the memory cell structure 21 and the cell wiring structure 22 over the substrate 101a.

Referring to FIG. 13 again, the driver circuit wafer 2b may include a substrate 301, a cell driver circuit 31, a driver circuit wiring structure 32, and a driver circuit capping insulation layer 360. The cell driver circuit 31 may include at least one driver transistor disposed in the substrate 301. The at least one driver transistor may include a gate dielectric layer 311 and a gate electrode layer 312 that are disposed on the substrate 301, and well regions 313 disposed in the substrate 301.

The driver circuit wiring structure 32 may be formed over the cell driver circuit 31. The driver circuit wiring structure 32 may include a lower driver circuit pattern layer 320 electrically connected to the gate electrode layer 312 and the well regions 313 through a lower contact layer 320C. In addition, the driver circuit wiring structure 32 may include at least one of upper driver circuit pattern layers 330 and 340 electrically connected to the lower driver circuit pattern layer 320 through at least one of interlayer contact layers 330C and 340C. The driver circuit structure 32 may include a driver circuit bonding pad 350 electrically connected to the at least one of upper driver circuit pattern layers 330 and 340. The driver circuit bonding pad 350 may be electrically connected to the at least one of upper drive circuit pattern layers 330 and 340 through a pad contact layer 350C. The driver circuit capping insulation layer 360 may be formed to cover the cell driver circuit 31 and the driver circuit wiring structure 32 over the substrate 301.

Referring to FIG. 14, the cell wafer 2a and the driver circuit wafer 2b may be bonded to each other. In this case, the cell bonding pad 220 of the cell wafer 2a and the driver circuit bonding pad 350 of the driver circuit wafer 2b may be electrically connected to each other. Accordingly, the cell bonding pad 220 may contact the driver circuit bonding pad 350, and the cell capping insulation layer 230 may contact the driver circuit capping insulation layer 360.

Through the above-described processes, a semiconductor device 2 according to an embodiment of the present disclosure may be fabricated. The semiconductor device 2 may be fabricated by forming a cell structure 21 and a cell driver circuit 31 on separate substrates, and then bonding the separate substrates to each other. Accordingly, in the semiconductor device 2, the cell driver circuit 31 may be disposed on the cell structure 21 with respect to the substrate 101a of the cell wafer 2a.

According to the method of fabricating the semiconductor device according to FIGS. 13 and 14, as compared with the case of forming the cell driving circuit 31 on a single substrate and forming the cell structure 21 on the cell driving circuit 31, the process difficulty may be reduced. As an example, it is possible to prevent the cell driving circuit 31, which is formed below the cell structure 21, from being thermally damaged by thermal processes used in forming the cell structure 21.

Concepts have been disclosed in conjunction with some embodiments as described above. Those skilled in the art will appreciate that various modifications, additions, and substitutions are possible, without departing from the scope and spirit of the present disclosure. Accordingly, the embodiments disclosed in the present specification should be considered from not a restrictive standpoint but rather from an illustrative standpoint. The scope of the concepts is not limited to the above descriptions but defined by the accompanying claims, and all of distinctive features in the equivalent scope should be construed as being included in the concepts.

What is claimed is:

1. A semiconductor device comprising:
a substrate;
a source electrode layer and a drain electrode layer that are disposed over the substrate to be spaced apart from each other in a direction substantially perpendicular to a surface of the substrate;
first and second oxide channel layers that extend in the direction substantially perpendicular to the surface of the substrate between the source electrode layer and the drain electrode layer and that have different band gap energies from each other;
a ferroelectric layer disposed adjacent to the first and second oxide channel layers; and
a gate electrode layer disposed on the ferroelectric layer.

2. The semiconductor device of claim 1, wherein the first and second oxide channel layers are each disposed to contact the source electrode layer and the drain electrode layer, respectively.

3. The semiconductor device of claim 1, further comprising first and second channel passivation layers disposed over the substrate to contact the first and second oxide channel layers, respectively.

4. The semiconductor device of claim 3, wherein each of the first and second channel passivation layers includes nitride.

5. The semiconductor device of claim 3, wherein the first channel passivation layer extends in the direction substantially perpendicular to the surface of the substrate, and is disposed to passivate side surfaces of the source electrode layer, the first oxide channel layer, and the drain electrode layer.

6. The semiconductor device of claim 3, wherein the second channel passivation layer is disposed to contact a side surface of the second oxide channel layer between the source electrode layer and the drain electrode layer.

7. The semiconductor device of claim 1, wherein the second oxide channel layer has a band gap energy smaller than a band gap energy of the first oxide channel layer.

8. The semiconductor device of claim 7, wherein each of the first and second oxide channel layers includes at least one selected from the group consisting of gallium oxide, indium gallium oxide, indium selenium oxide, indium magnesium oxide, indium gallium zinc oxide, indium tin gallium zinc oxide, and indium silver oxide.

9. The semiconductor device of claim 1,
wherein the first oxide channel layer and the second oxide channel layer are disposed to be in contact with each other, and
wherein the ferroelectric layer is disposed to be in contact with one of the first and second oxide channel layers.

10. The semiconductor device of claim 1, further comprising electrons accumulated at an interface between the first and second oxide channel layers when a write voltage having a positive bias is applied to the gate electrode layer.

11. The semiconductor device of claim 1, further comprising a cell driver circuit disposed in the substrate or disposed over the source electrode layer and the drain electrode.
